(19) United States
(12) Patent Application Publication
(10) Pub. No.: US 2015/0097278 A1
(43) Pub. Date: Apr. 9, 2015

(54) SURFACE MOUNT SEMICONDUCTOR DEVICE WITH ADDITIONAL BOTTOM FACE CONTACTS

(71) Applicants: Zhigang Bai, Tianjin (CN); Yin Kheng Au, Petaling Jaya (MY); Lan Chu Tan, Singapore (SG); Jinzhong Yao, Tianjin (CN)

(72) Inventors: Zhigang Bai, Tianjin (CN); Yin Kheng Au, Petaling Jaya (MY); Lan Chu Tan, Singapore (SG); Jinzhong Yao, Tianjin (CN)

(73) Assignee: Freescale Semiconductor, Inc., Austin, TX (US)

(21) Appl. No.: 14/459,328

(22) Filed: Aug. 14, 2014

(30) Foreign Application Priority Data
Oct. 9, 2013 (CN) 201310467401.3

(51) Int. Cl. H01L 23/495

(52) U.S. Cl. CPC H01L 23/49575; H01L 23/49517
USPC 257/676; 438/123

(57) ABSTRACT

Assembling a surface mount semiconductor device includes providing a lead frame structure with peripheral leads and additional bottom face contacts integral with frame members. Outer portions of the bottom face contact members are interposed between inner portions of adjacent pairs of the peripheral leads. A package body is formed by encapsulating the lead frame structure in which the frame members are positioned outside a side edge surface. The peripheral leads and the bottom face contact members project between the side edge surface of the package body and the frame members. The frame members are cut and the peripheral leads and the bottom face contact members are separated and electrically isolated from each other.

### BACKGROUND OF THE INVENTION

The present invention is directed to a packaged semiconductor device and, more particularly, to a surface mount semiconductor device having leads that project from the sides of the package body as well as additional exposed electrical contacts in a bottom face of the package body.

Semiconductor device packaging fulfills basic functions such as providing electric connections and protecting the die against mechanical and environmental stresses. A surface mount semiconductor device has exposed electrical contacts that allow it to be mounted on a support, such as a printed circuit board (PCB), for example, where its exposed electrical contacts provide for electrical communication with the PCB or with other circuitry or devices by way of the PCB. That is, the exposed electrical contacts of the device can be soldered directly to corresponding electrical contact pads on the support, providing mechanical attachment as well as electrical connections. Semiconductor devices are commonly packaged for surface mounting by encapsulating one or more semiconductor dies with a molding compound to form the package body.

The semiconductor device commonly has an electrically and thermally conductive metal flag (also called die pad or paddle), which supports the die and also participates in cooling the device, whether or not the flag is exposed at the surface of the encapsulation. It is common to facilitate manufacturing operations by performing many of the operations on an array of the semiconductor dies mounted on an array of flags that are linked together, the links being later severed with a singulation process. The links are typically provided by a frame structure (such as an array of lead frames), which has an array of the flags connected by tie bars to frame members that are removed or cut off and discarded during singulation. The exposed electrical contacts are supported directly or indirectly by the frame members and/or the flags and/or additional connection bars in the frame structure until the dies are encapsulated, and then the exposed electrical contacts are isolated from each other during singulation. This technique is applicable to devices where the exposed electrical contacts are disposed outside the flag and the semiconductor die, on two opposite sides or around all four sides.

In one type of surface mount semiconductor device, the flag is exposed at its bottom face while in another type the flag as well as the die are embedded in the mold compound. In one type of package, known as quad flat no-lead (QFN), the peripheral exposed electrical contacts are positioned in the bottom face of the body of the device and at or close to its edge surface. In a quad flat package (QFP), the peripheral exposed electrical contacts are leads that project from the sides of the body of the device and down to the level of the bottom face of the device in a gull-wing or J-shape configuration.

Various techniques are available for connecting the exposed electrical contacts of the device internally with electrical contact pads of the semiconductor die. In a wire bond package, typically the back face of the die is mounted on the flag and the contact pads on the active face of the die are connected to the exposed electrical contacts of the package with bond wires.

Continued reduction in the size of semiconductor devices and increase in their complexity and functionality result in a need for an increase in the number of exposed electrical contacts and a reduction in the spacing between the exposed electrical contacts. A conventional technique for singulating the devices and isolating the exposed electrical contacts is sawing the frame structure. However, there are circumstances where a simpler and less costly technique than saw singulation is desirable.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale. In particular, horizontal scales are not necessarily the same as vertical scales, numbers of elements may have been reduced and spacing between elements may have been increased relative to the widths of the elements.

FIG. 1 is a schematic sectional view of a conventional surface mount semiconductor device;

FIG. 2 is a schematic plan view of a lead frame structure and semiconductor die during assembly of the semiconductor device of FIG. 1;

FIG. 3 is a schematic detailed sectional view along the line 1-1 of FIG. 4 of a surface mount semiconductor device in accordance with an embodiment of the present invention;

FIG. 4 is a schematic plan view of the semiconductor device of FIG. 3;

FIG. 5 is a schematic detailed sectional view along the line 5-5 of FIG. 6 of a lead frame structure and semiconductor die during assembly of the semiconductor device of FIG. 3;

FIG. 6 is a schematic plan view of the lead frame structure and semiconductor die of FIG. 5;

FIGS. 7 and 8 are similar sectional views, taken along the lines 7-7 of FIGS. 8 and 8-8 of FIG. 7 respectively, of details of the area shown in chain-dotted lines of the lead frame structure of FIGS. 5 and 6 during a method of assembly in accordance with one embodiment of the invention;

FIG. 9 is a schematic detailed sectional view along the line 9-9 of FIG. 10 of a lead frame structure and semiconductor die during assembly of a surface mount semiconductor device in accordance with another embodiment of the present invention;

FIG. 10 is a schematic plan view of the lead frame structure and semiconductor die of FIG. 9;

FIGS. 11 and 12 are similar sectional views, taken along the lines 11-11 of FIGS. 12 and 12-12 of FIG. 11 respectively, of details of the area shown in dotted lines of the lead frame structure of FIGS. 9 and 10 during a assembly in accordance with an embodiment of the present invention; and

FIG. 13 is a flow chart of a method of assembling a surface mount semiconductor device in accordance with an embodiment of the present invention.

### DETAILED DESCRIPTION OF THE INVENTION

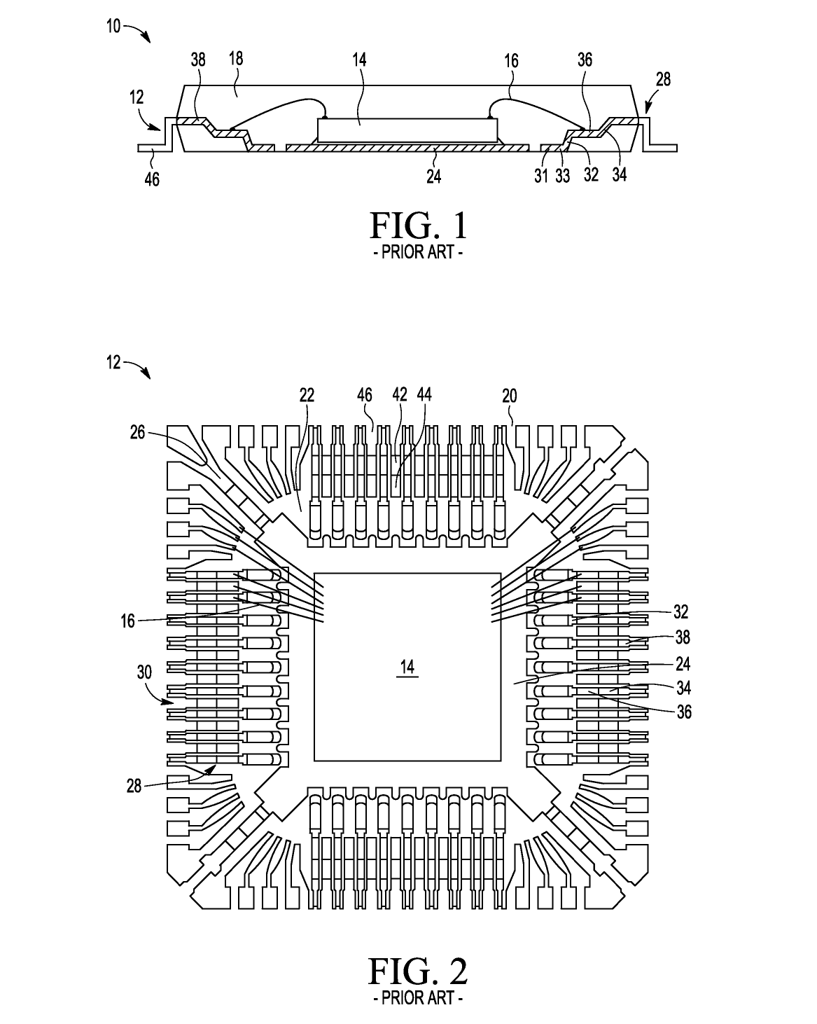

FIGS. 1 and 2 illustrate a conventional surface mount semiconductor device 10. The semiconductor device 10 is made using a lead frame structure 12. The lead frame structure 12 includes a plurality of frame members or dam bars 20, a flag 24, four sets of bottom face electrical contact members 28, and four sets of peripheral electrical leads 30. The peripheral leads 30 and the bottom face electrical contact members 28 are integral with the frame members 20. Outer portions of the bottom face electrical contact members 28 are interposed between inner portions of respective adjacent pairs of the peripheral electrical leads 30.

A semiconductor die 14 is attached to the flag 24 and is connected electrically with the peripheral electrical leads 30 and the bottom face electrical contact members 28 with bond wires 16. The semiconductor die 14 is encapsulated in a package body 18 and the frame members 20 are removed by a conventional process to electrically isolate the peripheral electrical leads 30 and the bottom face electrical contact members 28 from each other. The peripheral electrical leads 30 project from the side edge surface of the package body 18, and surfaces 33 of the bottom face electrical contact members 28 are exposed in the bottom face of the package body 18.

In the finished semiconductor device 10, the outer ends of the bottom face electrical contact members 28 are exposed flush with the side edge surface of the package body 18. In this configuration, the removal of the frame members 20 is likely to cause de-lamination of the outer ends of the bottom face electrical contact members 28 and the molding compound of the package body 18. Moreover, defects may occur during the operation of severing and removing the frame members 20 and cause electrical short-circuits between the outer ends of the bottom face electrical contact members 28 and the adjacent peripheral electrical leads 30.

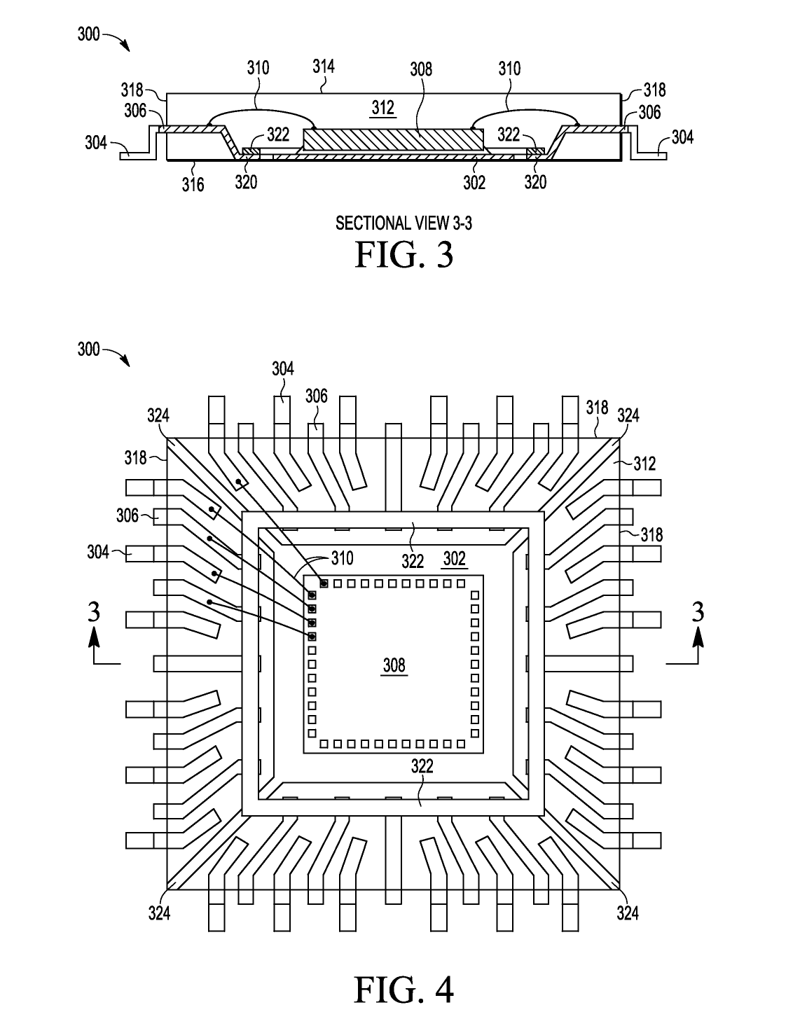

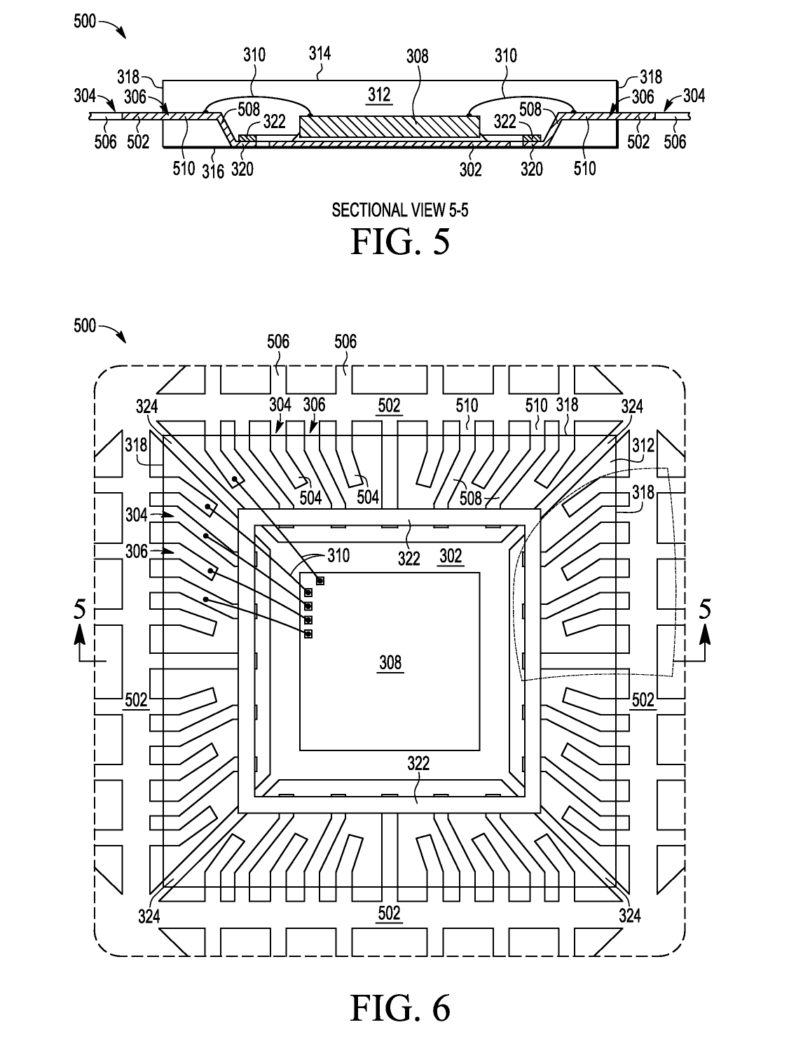

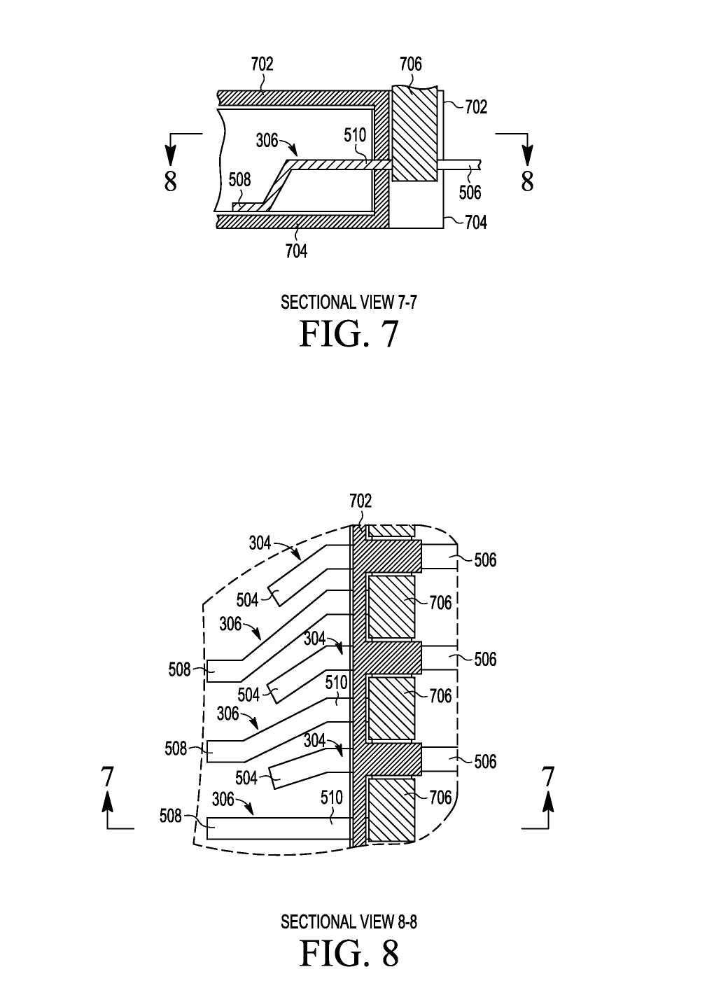

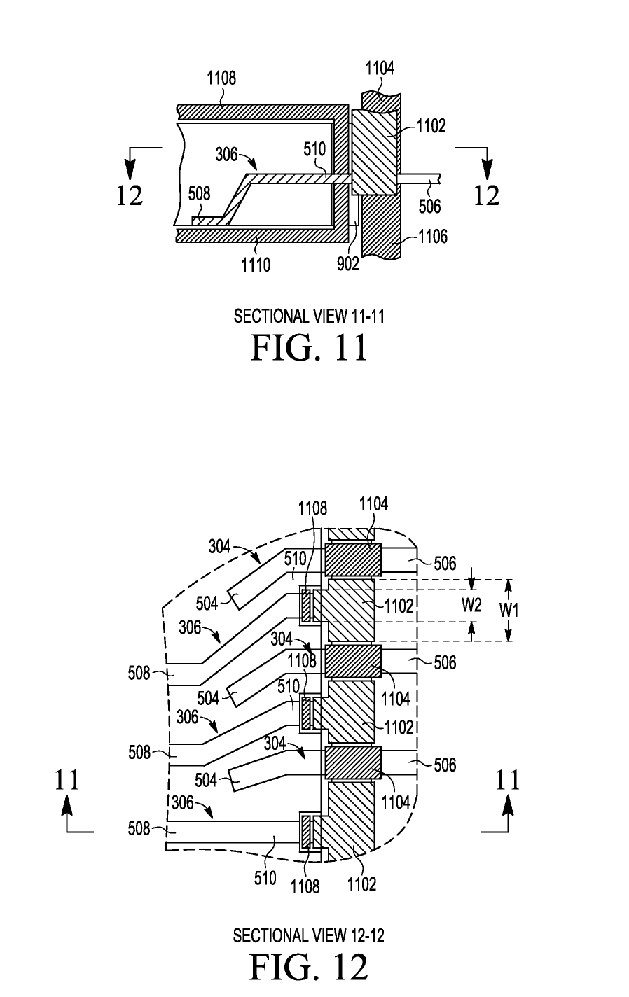

FIGS. 3 to 13 illustrate examples of surface mount semiconductor devices 300, 900 and a method 1300 of assembling surface mount semiconductor devices in accordance with embodiments of the present invention. A method of assembling a surface mount semiconductor device such as the devices 300 and 900 comprises providing a frame structure such as 500 including a flag 302, a plurality of frame members 502, a plurality of sets of peripheral electrical contact members 304 and a plurality of sets of bottom face electrical contact members 306 positioned at least at two opposite sides of the frame structure 500. The peripheral electrical contact members 304 and the bottom face electrical contact members 306 are integral with the frame members 502 and have respective inner and outer portions 504, 506 and 508, 510, the outer portions 510 of the bottom face electrical contact members 306 being interposed between the inner portions 504 of respective adjacent pairs of the peripheral electrical contact members 304. A semiconductor die 308 is attached to the flag 302 and is connected electrically with the peripheral electrical contact members 304 and the bottom face electrical contact members 306, in this example by bonding wires 310, of which only some are shown in the drawings for simplicity.

The semiconductor die 308, the inner portions 504 of the peripheral electrical contact members 304 and the outer portions 510 of the bottom face electrical contact members 306 are encapsulated with a mold compound to form a package body 312 having top and bottom faces 314 and 316 and a side edge surface 318, with the frame members 502 positioned outside the package body 312. The peripheral electrical contact members 304 and the bottom face electrical contact members 306 project between the side edge surface 318 of the package body 312 and the frame members 502, and surfaces 320 of the inner portions 508 of the bottom face electrical contact members 306 are exposed in the bottom face 316 of the package body 312. The frame members 502 are severed and the peripheral electrical contact members 104 and the bottom face electrical contact members 106 separated and electrically isolated from each other. The severing operation includes punching out portions of the frame members 502 while supporting portions of the bottom face electrical contact members 306 between the punched out portions and the package body 312.

The package body 312 is shown as if it were semi-transparent in certain views, for the purposes of visualization of elements which would otherwise be hidden.

In this example the semiconductor devices 300, 900 are quad flat package (QFP) devices with the outer portions 506 of the peripheral electrical contact members 304 exposed and projecting from the side edge surface 318 of the package body 312, on four sides of the package body 312. However, it will be appreciated that other configurations are possible, including in-line (with peripheral electrical contact members 304 on only two opposite sides of the package body 312) or ‘no-lead’ (QFN) configurations, for example.

In this example of a QFP device, the outer portions 506 of the peripheral electrical contact members 304 project outside the frame members 502 in the frame structure 500, and severing the frame members 502 includes supporting portions of the peripheral electrical contact members 304 between adjacent punched out portions. Supporting portions of the electrical contact members 304, 306 includes clamping them between upper and lower clamp members 702 and 704, 1104 and 1106, 1108 and 1110, in this example.

An electrically insulating member 322 may be attached to back surfaces of the inner portions 508 of the bottom face electrical contact members 306. The electrically insulating member 322 can participate in supporting the inner portions 508 of the bottom face electrical contact members 306 during encapsulation and can hinder resin bleed from the mold compound onto the exposed surfaces 320 of the inner portions 508. The electrically insulating member 322 may be an adhesive tape, in one example. In another example, the electrically insulating member 322 may be a frame attached to the back surfaces of the inner portions 508 by epoxy adhesive. The electrically insulating member 322 may be attached also to tie bars 324 that support the flag 302 from the frame members 502. A resin bleed stop slot at the inner ends of the bottom face contacts may further reduce resin bleed onto the exposed surfaces 320 of the inner portions 508.

The semiconductor die 308 may be connected electrically with the inner portions 504 of the peripheral electrical contact members 304 and the outer portions 510 of the bottom face electrical contact members 306. This can facilitate and improve the quality of the connections, for example where bonding wires such as 310 are bonded to the contact members 304 and 306.

In the example of the surface mount semiconductor device 300, the side edge surface 318 of the package body 312 is straight on each side. The frame members 502 of the frame structure 500 are sufficiently far away from the side edge surface 318 of the package body 312 for the upper and lower clamp members 702 and 704 to pass between the punch tools 706 and the package body 312 and support the outer portions 510 of the bottom face electrical contact members 306. The frame members 502 may be severed by rectangular section punch tools 706. Extensions of the upper and lower clamp members 702 and 704 may pass between adjacent punch tools 706 to support the portions of the peripheral electrical contact members 304.

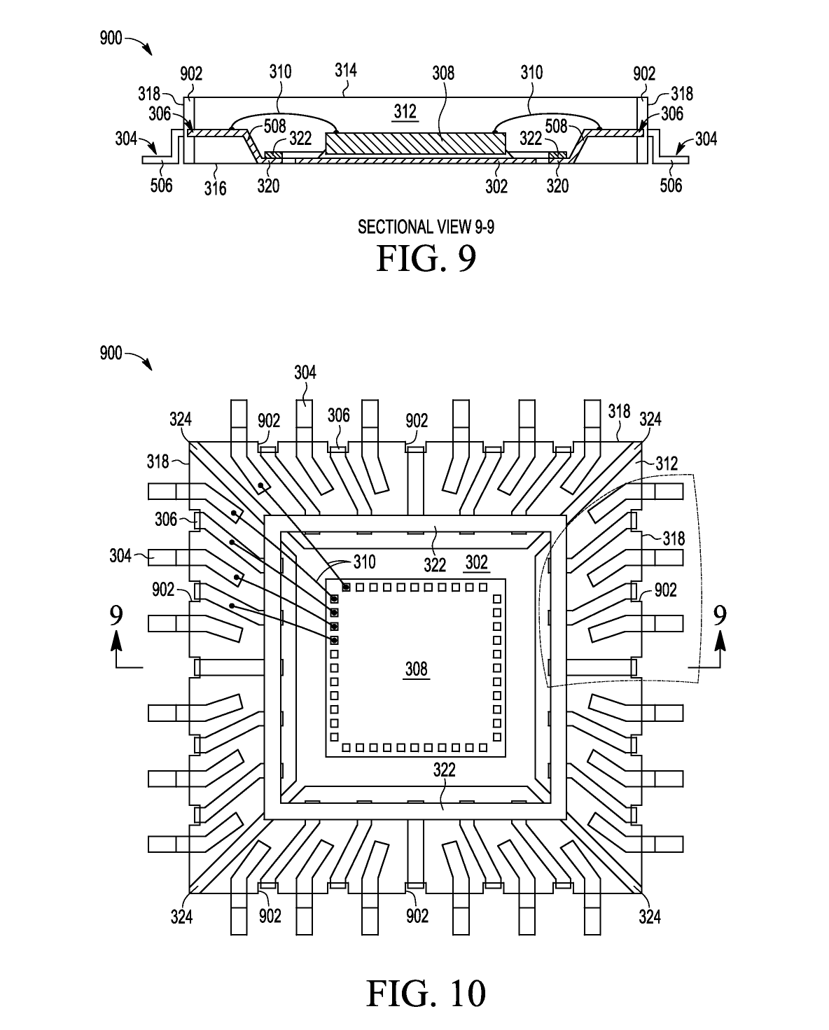

In the example of the surface mount semiconductor device 900, illustrated in FIGS. 9 to 12, the side edge surface 318 of the package body 312 has indentations 902. The bottom face electrical contact members 306 project outwards through the indentations 902, and the peripheral electrical contact members 304 project outwards between the indentations 902. The package body 312 can cover the peripheral electrical contact members 304 in the indentations 902 and provide an additional protection against any risk of short-circuits between the peripheral electrical contact members 304 and the interposed bottom face electrical contact members 306 at the side edge surface 318.

For the surface mount semiconductor device 900, severing the frame members 502 may include using T-section punch tools 1102 having first portions of a first width W1 outside the indentations 902, and second portions of a second width W2 narrower than the first width W1, the first portions punching out portions of the frame members 502, and the second portions punching out portions of the bottom face electrical contact members 306 within the indentations 902. Supporting portions of the peripheral electrical contact members 304 may include clamping them between rectangular section upper and lower clamp members 1104 and 1106 between the first portions of adjacent punch tools 1102. Supporting portions of the bottom face electrical contact members 306 may include clamping them in the indentations 902 between rectangular section upper and lower clamp members 1108 and 1110, in this example.

As shown in FIGS. 3 and 9, in these examples of the semiconductor devices 300 and 900 the outer portions 506 and 510 of the peripheral electrical contact members 304 and the bottom face electrical contact members 306 project from the side edge surface 318 of the package body 312 at a height intermediate between the top and bottom faces 314 and 316 and connect with the frame members 502 at that intermediate height before the frame members are severed. The bonding wires 310 that connect with the semiconductor die 308 are bonded to the inner portions 504 of the peripheral electrical contact members 304 and to the outer portions 510 of the bottom face electrical contact members 306 at the same intermediate height, which can facilitate the bonding operation. The inner portions 508 of the bottom face electrical contact members 306 are formed in the frame structure 500 with down sets to bring the exposed surfaces 320 to the level of the bottom face of the package body 312. After severing the frame members 502, in the case of the QFP devices illustrated the outer portions 502 of the peripheral electrical contact members 304 are trimmed and formed down into a gull-wing or J shape.

In the case of a QFN device (not shown), in the frame structure 500 the peripheral electrical contact members 304 and the bottom face electrical contact members 306 project from the side edge surface 318 of the package body 312 at the level of the bottom face 316 and connect with the frame members 502 at that bottom face level before the frame members are severed. The bonding wires 310 that connect with the semiconductor die 308 may be bonded to the inner portions 504 of the peripheral electrical contact members 304 and to the outer portions 510 of the bottom face electrical contact members 306 at a height intermediate between the top and bottom faces 314 and 316. The outer portions 506 and 510 of the peripheral electrical contact members 304 and the bottom face electrical contact members 306 are formed in the frame structure 500 with down sets to bring the outer portions 506 and 510 to the level of the bottom face of the package body 312 at the side edge surface 318. After severing the frame members 502, in the case of QFN devices the ends of the outer portions 502 of the peripheral electrical contact members 304 are trimmed and may be formed up to overlap the bottom of the side edge surface 318. The outer portions 510 of the bottom face electrical contact members 306 may be left exposed in the side edge surface 318 after trimming.

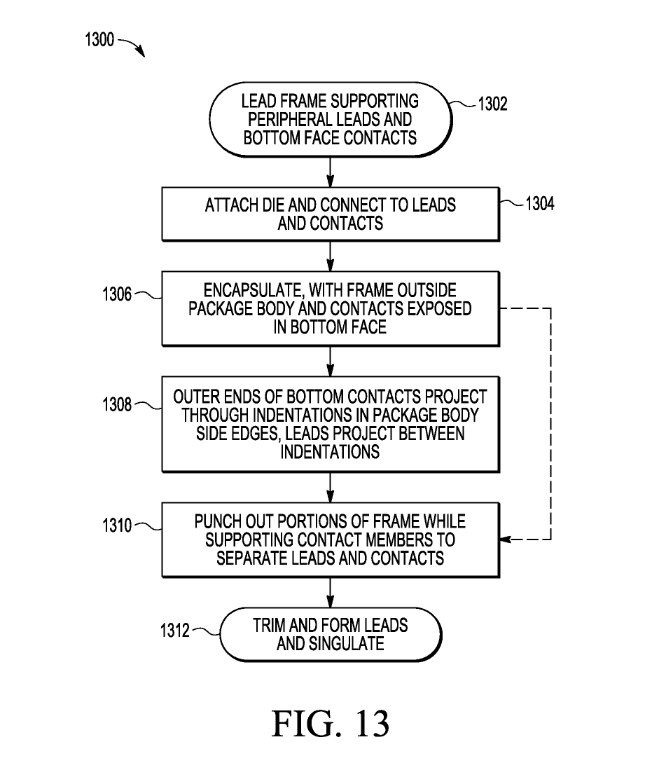

FIG. 13 is a flow chart of the method 1300 of assembling a semiconductor device such as 300 or 900. At 1302, the frame structure such as 500 including the flag 302, the frame members 502, the peripheral electrical contact members 304 and the bottom face electrical contact members 306 is provided. The electrically insulating member 322 may be attached to the frame structure provided. The semiconductor die 308 is attached to the flag 302 and is connected electrically with the peripheral electrical contact members 304 and the bottom face electrical contact members 306 at 1304. The semiconductor die 308, the inner portions 504 of the peripheral electrical contact members 304 and the outer portions 510 of the bottom face electrical contact members 306 are encapsulated with the mold compound at 1306, the frame members 502 being positioned outside the package body 312.

In the case of a semiconductor device such as 900, as shown at 1308, where the package body 312 has indentations 902, the bottom face electrical contact members 306 project outwards through the indentations 902, and the peripheral electrical contact members 304 project outwards between the indentations 902.

In the case of both the semiconductor devices such as 300 and 900, at 1310 the frame members 502 are severed to separate and electrically isolate the peripheral electrical contact members 104 and the bottom face electrical contact members 106 from each other. Severing the frame members 502 includes punching out portions of them while supporting portions of the bottom face electrical contact members 306 between the punched out portions and the package body 312.

The bottom face electrical contact members 306 enable an increase in the number of input/output (I/O) contacts provided on the semiconductor device 300 or 900 compared to a semiconductor device that only has peripheral electrical contact members like 304. An increase of 50% or more of I/O contacts can be obtained. Separating and isolating the exposed electrical contacts 304 and 306 by punch operations as described is simpler and less costly than operations such as sawing. The punch operations described incur reduced risks of defects due to de-lamination or short-circuit between adjacent contact members.

It will be appreciated that a semiconductor device such as 300 and 900 may include more than one semiconductor die 308. Although a single row of exposed bottom face contact surfaces 320 is shown around the flag 302, it will be appreciated that more than one row may be provided. It will also be appreciated that the flag 302 may be exposed in the bottom face 316 of the package body 312, as shown, or may be embedded in the package body 312 instead.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

In the claims, the word ‘comprising’ or ‘having’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

1. A method of assembling a surface mount semiconductor device, comprising:
providing a frame structure including a flag, a plurality of frame members, a plurality of sets of peripheral electrical contact members and a plurality of sets of bottom face electrical contact members positioned at least at two opposite sides of the frame structure;
wherein the peripheral electrical contact members and the bottom face electrical contact members are integral with the frame members and have respective inner and outer portions, the outer portions of the bottom face electrical contact members being interposed between the inner portions of respective adjacent pairs of the peripheral electrical contact members;
attaching to the flag a semiconductor die and connecting the semiconductor die electrically with the peripheral electrical contact members and the bottom face electrical contact members;
encapsulating the semiconductor die, the inner portions of the peripheral electrical contact members and the outer portions of the bottom face electrical contact members with a mold compound to form a package body having top and bottom faces and a side edge surface, with the frame members positioned outside the package body, with the peripheral electrical contact members and the bottom face electrical contact members projecting between the side edge surface of the package body and the frame members, and with surfaces of the inner portions of the bottom face electrical contact members exposed in the bottom face of the package body; and
severing the frame members and separating and electrically isolating the peripheral electrical contact members and the bottom face electrical contact members from each other, including punching out portions of the frame members while supporting portions of the bottom face electrical contact members between the punched out portions and the package body.

2. The method of claim 1, wherein the semiconductor device is a quad flat package (QFP) device with the outer portions of the peripheral electrical contact members exposed and projecting from the side edge surface of the package body, wherein the outer portions of the peripheral electrical contact members project outside the frame members in the frame structure, and wherein severing the frame members includes supporting portions of the peripheral electrical contact members between adjacent punched out portions.

3. The method of claim 1, wherein supporting portions of the electrical contact members includes clamping them between upper and lower clamp members.

4. The method of claim 1, wherein an electrically insulating member is attached to back surfaces of the inner portions of the bottom face electrical contact members, participates in supporting the inner portions of the bottom face electrical contact members during encapsulation and hinders resin bleed from the mold compound onto the exposed surfaces of the inner portions of the bottom face electrical contact members.

5. The method of claim 1, wherein the semiconductor die is connected electrically with the inner portions of the peripheral electrical contact members and the outer portions of the bottom face electrical contact members.

6. A method of assembling a surface mount semiconductor device, comprising:
providing a frame structure including a flag, a plurality of frame members, a plurality of sets of peripheral electrical contact members and a plurality of sets of bottom face electrical contact members positioned at least at two opposite sides of the frame structure;
wherein the peripheral electrical contact members and the bottom face electrical contact members are integral with the frame members and have respective inner and outer portions, the outer portions of the bottom face electrical contact members being interposed between respective adjacent pairs of the peripheral electrical contact members;
attaching to the flag a semiconductor die and connecting the semiconductor die electrically with the inner portions of the peripheral electrical contact members and the outer portions of the bottom face electrical contact members;
encapsulating the semiconductor die, the inner portions of the peripheral electrical contact members and the outer portions of the bottom face electrical contact members with a mold compound to form a package body having top and bottom faces and a side edge surface with the frame members positioned outside the package body, and with surfaces of the inner portions of the bottom face electrical contact members exposed in the bottom face of the package body;
wherein the side edge surface of the package body has indentations, with the bottom face electrical contact members projecting through the indentations to the frame members, and with the peripheral electrical contact members projecting from the side edge surface of the package body between the indentations to the frame members; and
severing the frame members and separating and electrically isolating the peripheral electrical contact members and the bottom face electrical contact members from each other, including punching out portions of the frame members and integral portions of the bottom face electrical contact members while supporting portions of the bottom face electrical contact members between the punched out portions and the package body within the indentations.

7. The method of claim 6, wherein the semiconductor device is a quad flat package (QFP) device with the outer portions of the peripheral electrical contact members exposed and projecting from the side edge surface of the package body, wherein the outer portions of the peripheral electrical contact members project outside the frame members in the frame structure, and wherein severing the frame members includes supporting portions of the peripheral electrical contact members between adjacent punched out portions.

8. The method of claim 6, wherein supporting portions of the electrical contact members includes clamping them between upper and lower clamp members.

9. The method of claim 6, wherein T-section punch tools having first portions of a first width, and second portions of a second width narrower than the first width severing the frame members includes using, are used for severing, wherein the first portions punch out portions of the frame members, and the second portions punch out portions of the bottom face electrical contact members within the indentations.

10. The method of claim 6, wherein an electrically insulating member is attached to back surfaces of the inner portions of the bottom face electrical contact members, for participating in supporting the inner portions of the bottom face electrical contact members during encapsulation and hindering resin bleed from the mold compound onto the exposed surfaces of the inner portions of the bottom face electrical contact members.

11. The method of claim 6, wherein the semiconductor die is connected electrically with the inner portions of the peripheral electrical contact members and the outer portions of the bottom face electrical contact members.

12. A surface mount semiconductor device, comprising:
a semiconductor die;
a package body having top and bottom faces and a side edge surface, wherein the semiconductor die is encapsulated by package body;
a plurality of peripheral electrical contact members positioned at least at two opposite sides of the package body and having respective inner portions connected electrically with the semiconductor die and supported in the package body, and outer exposed contact portions whose ends project from the side edge surface and which allow for connection to an external electrical circuit; and
a plurality of bottom face electrical contact members positioned at least at the two opposite sides of the package body and having respective outer portions connected electrically with the semiconductor die and supported in the package body and whose ends project from the side edge surface, and inner portions having surfaces that are exposed in the bottom face of the package body and allow for connection to the external electrical circuit, the outer portions of the bottom face electrical contact members being interposed between the inner portions of respective adjacent pairs of the peripheral electrical contact members.

13. The semiconductor device of claim 12, wherein the semiconductor device is a quad flat package (QFP) device with the outer portions of the peripheral electrical contact members exposed and projecting from the side edge surface of the package body, and wherein the outer portions of the peripheral electrical contact members project further outwards from the package body than the outer portions of the bottom face electrical contact members.

14. The semiconductor device of claim 12, wherein the side edge surface of the package body has indentations through which the bottom face electrical contact members project outwards from, and the peripheral electrical contact members project outwards between the indentations.

15. The semiconductor device of claim 12, wherein the semiconductor die is connected electrically with the inner portions of the peripheral electrical contact members and the outer portions of the bottom face electrical contact members.
